(19) United States
(12) Patent Application Publication
(10) Pub. No.: US 2024/0003007 A1
(43) Pub. Date: Jan. 4, 2024

(54) METHOD OF MANUFACTURING INTEGRATED CIRCUIT DEVICE

(71) Applicant: SAMSUNG ELECTRONICS CO., LTD., SUWON-SI (KR)

(72) Inventors: PYUNG MOON, SUWON-SI (KR); KIHYUN KIM, SUWON-SI (KR); HYOUNGSUB KIM, SUWON-SI (KR); HOIJOON KIM, SUWON-SI (KR); GEUNYOUNG YEOM, SUWON-SI (KR); KONGSOO LEE, SUWON-SI (KR); HEESOO LEE, SUWON-SI (KR)

(73) Assignee: RESEARCH & BUSINESS FOUNDATION SUNGKYUNKWAN UNIVERSITY, SUWON-SI (KR)

(21) Appl. No.: 18/138,192

(22) Filed: Apr. 24, 2023

(30) Foreign Application Priority Data
Jun. 29, 2022 (KR) 10-2022-0079995

(51) Int. Cl. C23C 16/455; H01J 37/32; H01L 29/16; H01L 29/51

(52) U.S. Cl. CPC C23C 16/45536; H01L 29/517; H01L 29/1606; H01J 37/32357

(57) ABSTRACT

A method of manufacturing an integrated circuit device includes alternately stacking sacrificial semiconductor layers and channel layers on a substrate to form a stack structure, forming source regions and drain regions on both sides of the stack structure, forming a gate space between the channel layers by removing the sacrificial semiconductor layers, forming the channel layers to be spaced apart from each other in a perpendicular direction to the substrate, performing a plasma treatment of boron trichloride (BCL₃) on the channel layers, forming gate dielectric layers on the channel layers on which the plasma treatment of boron trichloride (BCL₃) is performed, and forming gate layers covering the gate dielectric layers in the gate space.

### CROSS-REFERENCE TO RELATED APPLICATION

A claim of priority under 35 U.S.C. § 119 is made to Korean Patent Application No. 10-2022-0079995, filed on Jun. 29, 2022, in the Korean Intellectual Property Office, the disclosure of which is incorporated by reference herein in its entirety.

### BACKGROUND

The inventive concept relates to a method of manufacturing an integrated circuit device, and more particularly, to a method of manufacturing an integrated circuit device including deposition of a relatively uniform high-K dielectric layer.

A two-dimensional (2D) transition metal dichalcogenide (TDMC) may be adopted as a channel layer material of a next-generation transistor. A TDMC channel layer is free of defects or reactive groups on its surface, which may be make it difficult to uniformly deposit a high-K dielectric layer on the channel layer through an atomic layer deposition (ALD) process.

A variety of surface treatment methods have been proposed to allow for uniform deposition of a high-k dielectric layer during the ALD process, but these methods can result in an increase in off-current due to surface damage and oxidation.

### SUMMARY

The inventive concept provides an integrated circuit device having improved reliability by uniformly depositing a high-K dielectric layer on a channel layer including a two-dimensional (2D) material.

According to an aspect of the inventive concept, there is provided a method of manufacturing an integrated circuit device including alternately stacking sacrificial semiconductor layers and channel layers on a substrate to form a stack structure, forming source regions and drain regions on both sides of the stack structure, forming a gate space between the channel layers by removing the sacrificial semiconductor layers, forming the channel layers to be spaced apart from each other in a perpendicular direction to the substrate, and performing a plasma treatment of boron trichloride (BCL₃) on the channel layers.

According to another aspect of the inventive concept, there is provided a method of manufacturing an integrated circuit device including alternately stacking sacrificial semiconductor layers and channel layers on a substrate to form a stack structure, forming source regions and drain regions on both sides of the stack structure, forming a gate space between the channel layers by removing the sacrificial semiconductor layers, forming the channel layers to be spaced apart from each other in a perpendicular direction to the substrate, performing a plasma treatment on the channel layers, and forming gate dielectric layers on the channel layers on which the plasma treatment is performed, wherein the plasma treatment is one of plasma treatments of BF₃, BCl₃, BBr₃ or BI₃.

According to another aspect of the inventive concept, there is provided a method of manufacturing an integrated circuit device including forming a gate electrode protruding from a substrate in a vertical direction and having a shape having a height greater than a width, forming a channel layer on an upper surface of the gate insulating layer after coating the gate electrode with a gate insulating layer, forming a source electrode and a drain electrode electrically connected to the channel layer, performing a plasma treatment of boron trichloride (BCL₃) on the channel layer, and depositing a gate dielectric film on the channel layer on which the plasma treatment of boron trichloride (BCL₃) is performed.

According to another aspect of the inventive concepts, there is provided a method of manufacturing an integrated circuit device. The method includes alternately stacking sacrificial semiconductor layers and channel layers on a substrate to form a stack structure, forming source regions and drain regions on both sides of the stack structure, forming a gate space between the channel layers by removing the sacrificial semiconductor layers, forming the channel layers to be spaced apart from each other in a perpendicular direction to the substrate, performing a plasma treatment on the channel layers, forming gate dielectric layers on the channel layers on which the plasma treatment is performed, and forming gate layers covering the gate dielectric layers in the gate space. The plasma treatment is one of plasma treatments of BF₃, BBr₃ or BI₃.

### BRIEF DESCRIPTION OF THE DRAWINGS

Embodiments of the inventive concept will be more clearly understood from the detailed description that follows taken in conjunction with the accompanying drawings in which:

FIG. 1 is a flowchart for reference in describing a method of manufacturing an integrated circuit device;

FIG. 2 is a layout diagram of an integrated circuit device according to some embodiments;

FIG. 3 is a cross-sectional view taken along line X-X′ of FIG. 2;

FIG. 4 is a cross-sectional view taken along line Y-Y′ of FIG. 2;

FIGS. 5 and 6 are cross-sectional views illustrating integrated circuit devices according to some embodiments;

FIGS. 7A, 7B, 8A, 8B, 9, 10, 11, 12, 13A, 13B, 14A, 14B, 15A, 15B, 16A and 16B are diagrams for reference in describing a process sequence of a method of manufacturing an integrated circuit device according to some embodiments, where FIGS. 7A, 8A, 9, 10, 11, 12, 13A, 14A, 15A and 16A are cross-sectional views of configurations of the process sequence along line X-X′ of FIG. 2, and FIGS. 7B, 8B, 13B, 14B, 15B and 16B are cross-sectional views of configurations of the process sequence along line Y-Y′ of FIG. 2;

FIGS. 17A and 17B are diagrams for reference in comparing surfaces of channel layers before and after a BCl₃ plasma treatment; and

FIG. 18 is a diagram illustrating an example of a plasma apparatus suitable for performing a BCl₃ plasma treatment.

### DETAILED DESCRIPTION OF THE EMBODIMENTS

Hereinafter, embodiments of the inventive concept will be described in detail with reference to the accompanying drawings. However, the inventive concept should not be construed as being limited to the embodiments described below and may be embodied in various other forms. The following embodiments are provided to fully convey the scope of the inventive concept to those skilled in the art, rather than to enable the inventive concept to be fully completed.

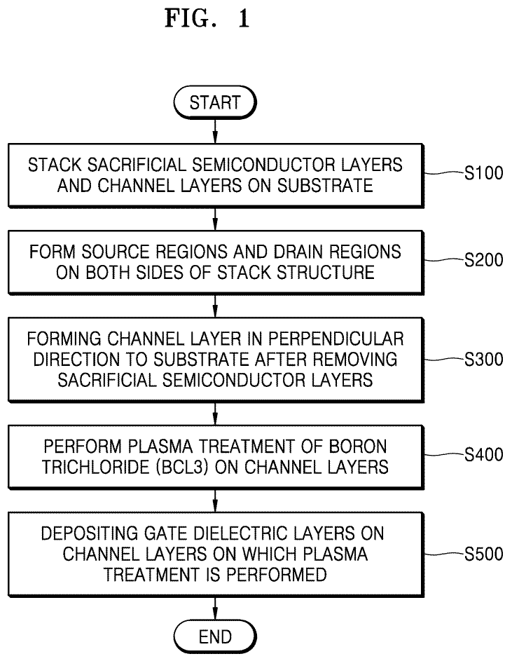

FIG. 1 is a flowchart for reference in describing a method of manufacturing an integrated circuit device.

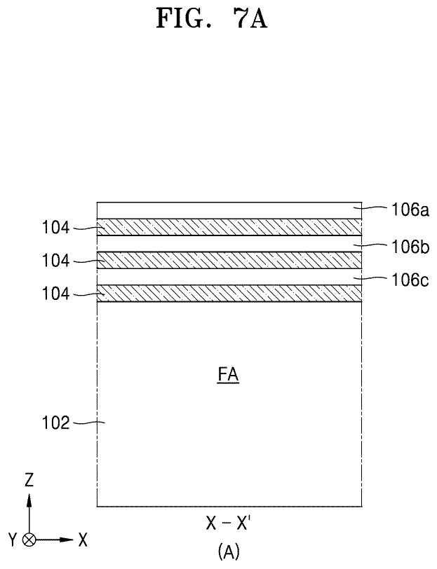

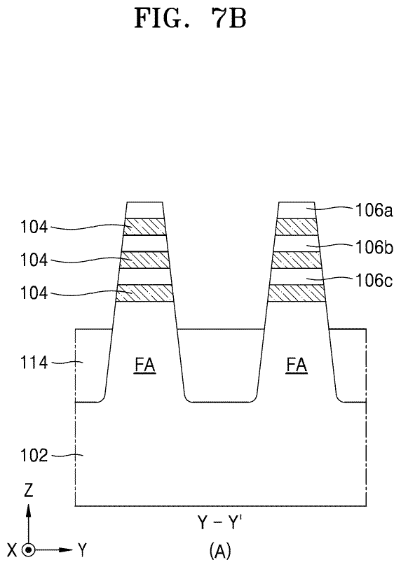

Referring to FIG. 1, the method of manufacturing an integrated circuit device includes stacking a sacrificial semiconductor layer and a channel layer on a substrate (S100), forming source regions and drain regions on both sides of a stack structure (S200), forming a channel layer in a direction perpendicular to the substrate after removing the sacrificial semiconductor layer (S300), performing plasma treatment of boron trichloride (BCL₃) on the channel layer (S400), and depositing a gate dielectric layer on the channel layer, on which the plasma treatment has been performed (S500). An example of these first (S100) to fifth (S500) operations will be described later with reference to FIGS. 7A to 16B.

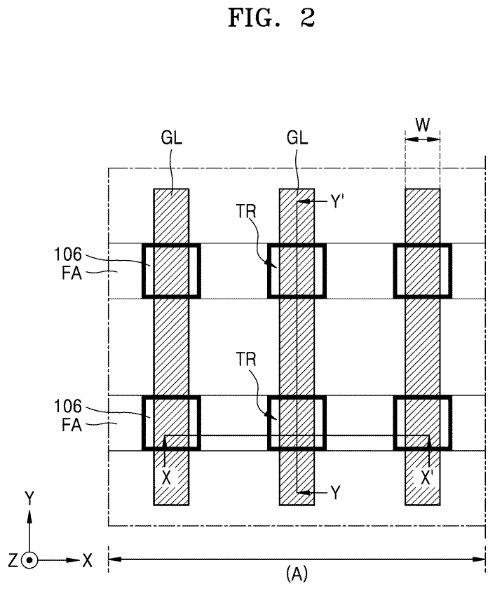

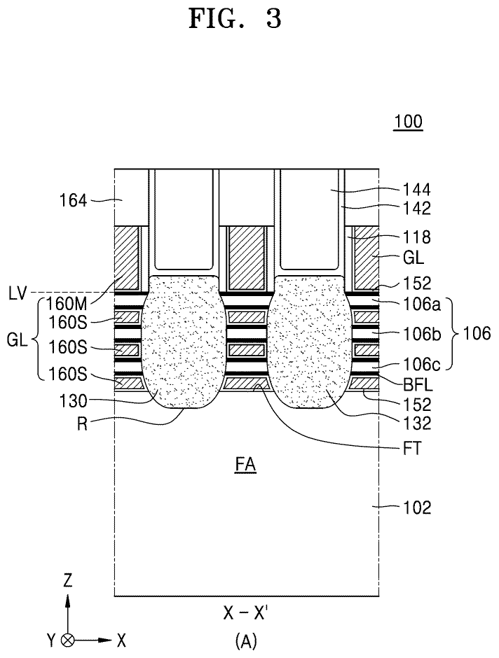

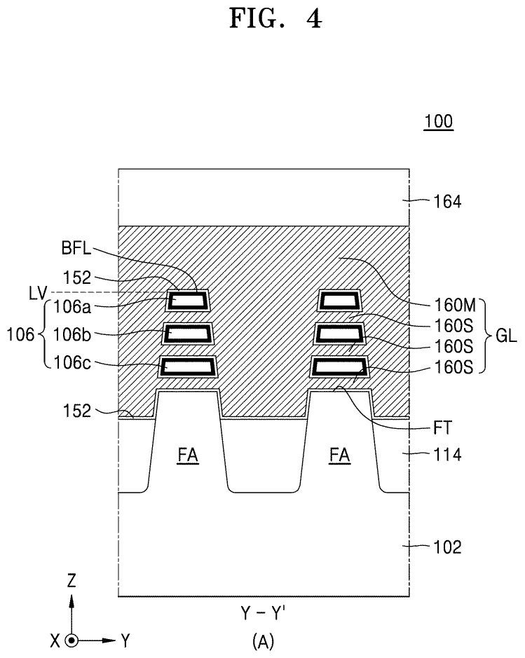

FIG. 2 is a layout diagram of an integrated circuit device according to some embodiments. FIG. 3 is a cross-sectional view taken along line X-X′ of FIG. 2, and FIG. 4 is a cross-sectional view taken along line Y-Y′ of FIG. 2.

Referring to FIGS. 3 and 4, an integrated circuit device 100 includes a substrate 102 including a device region (A). Although not shown, the substrate 102 may include a plurality of device regions (A) spaced apart from each other in a horizontal plane.

Referring to FIGS. 2 to 4, the integrated circuit device 100 may include a plurality of fin type active regions FA protruding upward in a vertical direction (Z direction) from the substrate 102 in the device region A and extending lengthwise in a first horizontal direction (X direction), and a plurality of channel layer stacks 106 respectively disposed on the plurality of fin type active regions FA. As used herein, the term “channel layer” means a conductive structure having a cross-section substantially perpendicular to a direction in which current flows.

The substrate 102 may include a semiconductor, such as Si or Ge, or a compound semiconductor, such as SiGe, SiC, GaAs, InAs, InGaAs, or InP. As used herein, the terms “SiGe”, “SiC”, “GaAs”, “InAs”, “InGaAs”, and “InP” mean materials including elements included in the respective terms, and are not chemical equations that indicate a stoichiometric relationship.

Referring to FIG. 4, a device isolation layer 114 covering both sidewalls of the plurality of fin type active regions FA may be disposed on the substrate 102 in the device region A. The device isolation layer 114 may include an oxide layer, a nitride layer, or a combination thereof.

Referring to FIGS. 2 to 4, a plurality of gate lines GL may be respectively disposed on the plurality of fin type active regions FA in the device region A. Each of the plurality of gate lines GL may extend in a second horizontal direction (Y direction) crossing the first horizontal direction (X direction). A plurality of channel layer stacks 106 may be respectively disposed on the plurality of fin type active regions FA in regions where the plurality of fin type active regions FA intersect with the plurality of gate lines GL. The plurality of channel layer stacks 106 may each include a plurality of channel layers 106a, 106b, and 106c overlapping each other in the vertical direction (Z direction) on the fin type active region FA. The plurality of channel layers 106a, 106b, and 106c may have different vertical distances (Z direction distances) from an upper surface of the fin type active region FA. The plurality of channel layers 106a, 106b, and 106c may include a first channel layer 106a, a second channel layer 106b, and a third channel layer 106c sequentially stacked on the fin type active region FA. The plurality of channel layer stacks 106 may each face a fin top surface FT of the fin type active region FA at a position spaced apart from each other in the vertical direction (Z direction) from the fin type active region FA.

In FIG. 2, the channel layer stack 106 has a substantially rectangular planar shape, but is not limited thereto. The channel layer stack 106 may have various planar shapes according to a planar shape of each of the fin type active region FA and the gate line GL. In the present example, the plurality of channel layer stacks 106 and the plurality of gate lines GL are disposed on one fin type active region FA, and the channel layer stack 106 is arranged in a line in the horizontal direction (X direction) on one fin type active region FA. However, the numbers of channel layer stacks 106 and gate lines GL disposed on one fin type active region FA are not limited to the particular examples illustrated in the drawings.

Each of the plurality of channel layers 106a, 106b, and 106c may have a channel region. For example, each of the plurality of channel layers 106a, 106b, and 106c may have a thickness selected within a range of about 4 nm to about 6 nm, but is not limited thereto. Here, the thickness of each of the plurality of channel layers 106a, 106b, and 106c means a size in the vertical direction (Z direction). In some embodiments, the plurality of channel layers 106a, 106b, and 106c may have substantially the same thickness in the vertical direction (Z direction). In other embodiments, at least some of the plurality of channel layers 106a, 106b, and 106c may have different thicknesses in the vertical direction (Z direction).

In some embodiments, referring to FIGS. 3 and 4, at least some of the plurality of channel layers 106a, 106b, and 106c included in one channel layer stack 106 may have different sizes in the first horizontal direction (X direction) and/or in the second horizontal direction (Y direction). For example, as illustrated in FIG. 4, the plurality of channel layers 106a, 106b, and 106c may have different widths in the second horizontal direction (Y direction), and may have gradually increasing widths in the second horizontal direction (Y direction) closer to the fin type active region FA. The width of the first channel layer 106a closest to the fin type active region FA in the second horizontal direction (Y direction) among the plurality of channel layers 106a, 106b, and 106c may be greater than the width of the third channel layer 106c farthest from the fin type active region FA in the second horizontal direction (Y direction).

In some embodiments, unlike illustrated in FIGS. 3 and 4, at least some of the plurality of channel layers 106a, 106b, and 106c may have the same size as each other in the first horizontal direction (X direction) and/or the second horizontal direction (Y direction).

As illustrated in FIG. 3, a plurality of recesses R may be formed in the fin type active region FA in the device region A. A level of a lowermost surface of each of the plurality of recesses R may be lower than the fin top surface FT. The term “level” used herein means a distance from the upper surface of the substrate 102 in the vertical direction (Z or-Z direction).

A plurality of source regions 130 and drain regions 132 may be disposed in the plurality of recesses R. The plurality of source regions 130 and drain regions 132 may have side walls facing the plurality of channel layers 106a, 106b, and 106c included in the adjacent channel layer stack 106, respectively. The plurality of source regions 130 and drain regions 132 may contact the plurality of channel layers 106a, 106b, and 106c included in the adjacent channel layer stack 106, respectively.

The plurality of source regions 130 and drain regions 132 may include an epitaxial grown semiconductor layer. In some embodiments, the plurality of source regions 130 and drain regions 132 may include a group IV element semiconductor, a group III-IIV compound semiconductor, or a combination thereof. In some embodiments, each of the plurality of source regions 130 and drain regions 132 may include a SI layer doped with an N-type dopant, a SiC layer doped with the N-type dopant, or a SiGe layer doped with a P-type dopant. The N-type dopant may be selected from phosphorus (P), arsenic (As), and antimony (Sb). The P-type dopant may be selected from boron B and gallium (Ga).

The plurality of gate lines GL may surround each of the plurality of channel layers 106a, 106b, and 106c and cover the channel layer stack 106 on the fin type active region FA. Each of the plurality of gate lines GL may include a main gate portion 160M and a plurality of sub-gate portions 160S. The main gate portion 160M may cover the upper surface of the channel layer stack 106 and extend in the second horizontal direction (Y direction). The plurality of sub-gate portions 160S may be integrally connected to the main gate portion 160M and may be each disposed between each of the plurality of channel layers 106a, 106b, and 106c, and between the first channel layer 106a and the fin type active region FA. In the vertical direction (Z direction), the thickness of each of the plurality of sub-gate portions 160S may be less than the thickness of the main gate portion 160M.

The gate line GL may include metal, metal nitride, metal carbide, or a combination of two or more thereof. The metal may be selected from Ti, W, Ru, Nb, Mo, Hf, Ni, Co, Pt, Yb, Tb, Dy, Er, and PD. The metal nitride may be selected from TiN and TaN. The metal carbide may be TiAlC. However, the material constituting the gate line GL is not limited to these examples.

A gate dielectric layer 152 may be provided between the channel layer stack 106 and the gate line GL. The gate dielectric layer 152 may cover the bottom and sidewalls of the main gate portion 160M in the gate line GL. For example, the gate dielectric layer 152 may be formed between the channel layer stack 106 and the gate line GL by an atomic layer deposition (ALD) method.

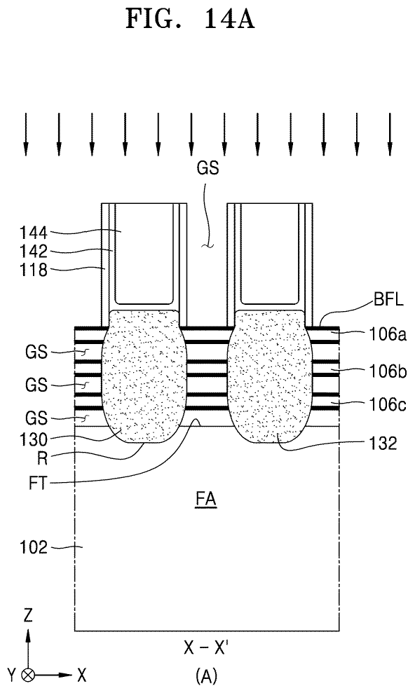

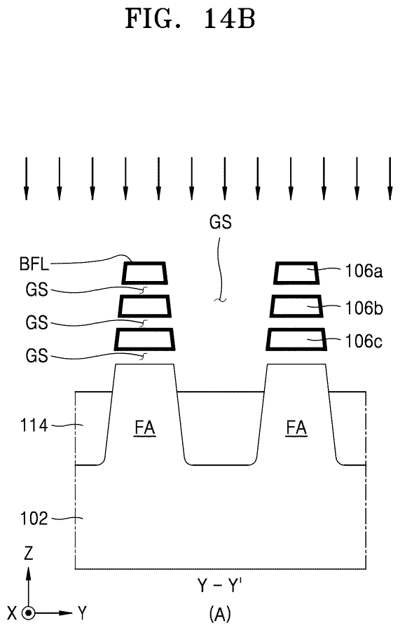

Before the gate dielectric layer 152 is provided to the channel layer stack 106, a plasma treatment of boron trichloride (BCL₃) may be performed on the surface of the channel layer stack 106. When the plasma treatment of boron trichloride (BCL₃) is performed on the channel layer stack 106, a plasma layer BFL may be formed on the surface of the channel layer stack 106. The plasma treatment of boron trichloride (BCL₃) is described in more detail below with reference to FIGS. 14A and 14B.

In some embodiments, the gate dielectric layer 152 may have a stack structure of an interface layer and a high-k layer. The interface layer may include a low dielectric material layer having a dielectric constant equal to or less than about 9, such as a silicon oxide layer, a silicon oxide layer, or a combination of two or more thereof. In some embodiments, the interface layer may be omitted. The high-k layer may include a material with a larger dielectric constant than that of a silicone oxide layer. For example, the high-k layer may have a dielectric constant of about 10 to about 25. The high-k layer may include hafnium oxide, but is not limited thereto.

A plurality of transistors TR may be formed in portions where the plurality of fin-type active regions FA intersect with the plurality of gate lines GL in the device region A.

In some embodiments, the plurality of channel layers 106a, 106b, and 106c may include semiconductor layers having the same element. In an example, each of the plurality of channel layers 106a, 106b, and 106c may include a Si layer. In some embodiments, each of the plurality of channel layers 106a, 106b, and 106c may include an undoped Si layer. In some embodiments, each of the plurality of channel layers 106a, 106b, and 106c may include a Si layer doped with a dopant of the same conductivity type as that of the source region 130 and the drain region 132. In some embodiments, each of the plurality of channel layers 106a, 106b, and 106c may include a Si layer doped with a dopant of a conductivity type opposite to that of the source region 130 and the drain region 132.

Referring to FIGS. 3 and 4, an upper surface of each of the plurality of gate lines GL in the device region A may be covered with a capping insulating pattern 164. The capping insulating pattern 164 may include a silicon nitride layer.

Referring to FIG. 3, each of the source regions 130 and the drain regions 132 in the device region A may include a part overlapping an insulating spacer 118 in the vertical direction (Z direction). For example, the width of the part of each of the plurality of source regions 130 and drain regions 132, which overlaps the insulating spacer 118 in the vertical direction (Z direction), in the first horizontal direction (X direction) may be selected within the range of about 0 nm to about 4 nm, but is not limited thereto.

Referring to FIGS. 3 and 4, in the device region A, the plurality of source regions 130 and drain regions 132, and the plurality of insulating spacers 118 may each be covered with an insulating liner 142. Each of the insulating liners 142 may include silicon nitride (SiN), silicon oxide (SiO), SiCN, SiBN, SiON, SiOCN, SiBCN, SiOC, or a combination of two or more thereof. In some embodiments, the insulating liner 142 may be omitted. An inter-gate insulating layer 144 may be disposed on the insulating liner 142. The inter-gate insulating layer 144 may include a silicon nitride layer, a silicon oxide layer, SiON, SiOCN, or a combination of two or more thereof. When the insulating liner 142 is omitted, the inter-gate insulating layer 144 may contact the plurality of source regions 130 and drain regions 132.

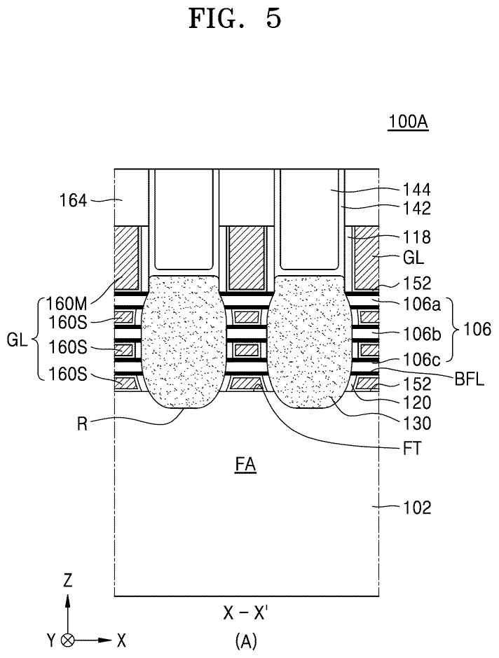

FIG. 5 is a cross-sectional view illustrating an integrated circuit device 100A according to some embodiments. FIG. 5 shows a partial configuration of a portion corresponding to the cross-section of the line X-X′ of FIG. 2. In FIG. 5, the same reference numerals as in FIG. 2A denote the same members, and redundant descriptions thereof are omitted herein.

Referring to FIG. 5, the integrated circuit device 100A may generally have the same configuration as that of the integrated circuit device 100 described with reference to FIGS. 1 and 2A to 2D. However, the integrated circuit device 100A further includes a plurality of inner insulating spacers 120 disposed between the plurality of sub-gate portions 160S and the source regions 130 and the drain regions 132, between each of the plurality of channel layers 106a, 106b, and 106c and between the first channel layer 106a and the fin type active region FA in the device region A.

Both sidewalls of each of the plurality of sub-gate portions 160S may be covered with the inner insulating spacer 120 with the gate dielectric layer 152 disposed therebetween. Each of the plurality of sub-gate portions 160S may be apart from the source region 130 and the drain region 132 with the gate dielectric layer 152 and the inner insulating spacer 120 disposed therebetween. The plurality of inner insulating spacers 120 may contact the source regions 130 and the drain regions 132, respectively. At least some of the plurality of inner insulating spacers 120 may overlap the insulating spacer 118 in the vertical direction (Z direction).

The plurality of inner insulating spacers 120 may include silicon nitride, silicon oxide, SiCN, SiBN, SiON, SiOCN, SiBCN, SiOC, or a combination of two or more thereof. In some embodiments, at least some of the plurality of inner insulating spacers 120 may further include an air gap. In some embodiments, the inner insulating spacer 120 may include the same material as that of the insulating spacer 118. In some embodiments, the insulating spacer 118 and the inner insulating spacer 120 may include different materials from each other.

The plurality of source regions 130 and drain regions 132 may respectively face the plurality of sub-gate portions 160S with the inner insulating spacer 120 and the gate dielectric layer 152 disposed therebetween in the first horizontal direction (X direction). The plurality of source regions 130 and drain regions 132 may not include a part contacting the gate dielectric layer 152.

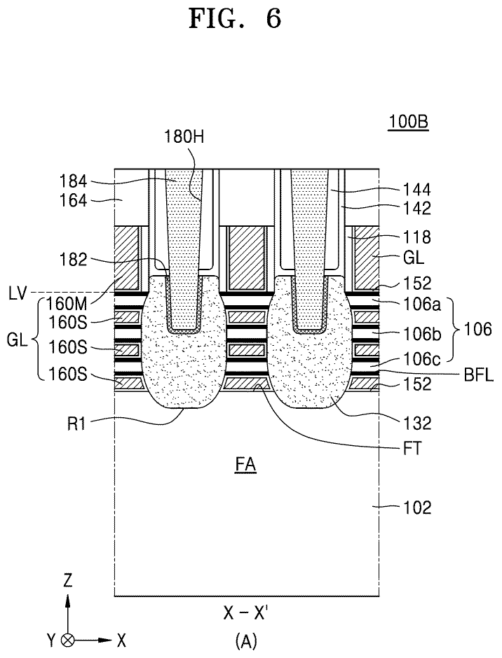

FIG. 6 is a cross-sectional view illustrating an integrated circuit device 100B according to some embodiments. FIG. 6 shows a partial configuration of a portion corresponding to the cross-section of the line X-X′ of FIG. 1. In FIG. 6, the same reference numerals as in FIG. 3 denote the same members, and redundant descriptions thereof are omitted herein.

Referring to FIG. 6, the integrated circuit device 100B may generally have the same configuration as the integrated circuit device 100 described with reference to FIGS. 2 to 4. However, the integrated circuit device 100B may further include a plurality of source/drain contacts 184 disposed on the plurality of source regions 130 and drain regions 132 in the device region A. A metal silicide layer 182 may be disposed between the source region 130 and the drain region 132 and the source/drain contact 184. Each of the plurality of source/drain contacts 184 may penetrate the insulating layer 144 and the insulating liner 142 in the vertical direction (Z direction) and may fill a contact hole 180H extending into the source region 130 and the drain region 132. The source region 130 and the drain region 132 may be apart from the source/drain contact 184 with the metal silicide layer 182 disposed therebetween. The source region 130 and the drain region 132 may surround the bottom of each of the plurality of source/drain contacts 184 from the outside of the contact hole 180H.

The metal silicide layer 182 may include titanium silicide, but is not limited thereto. In some embodiments, the metal silicide layer 182 may be omitted. Each of the plurality of source/drain contacts 184 may include a metal, a conductive metal nitride, or a combination thereof. For example, each of the plurality of source/drain contacts 184 may include W, Cu, Al, Ti, Ta, TiN, TaN, an alloy thereof, or a combination of two or more thereof.

FIGS. 7A, 7B, 8A, 8B, 9, 10, 11, 12, 13A, 13B, 14A, 14B, 15A, 15B, 16A and 16B are diagrams for reference in describing a process sequence of a method of manufacturing an integrated circuit device according to some embodiments. FIGS. 7A, 8A, 9, 10, 11, 12, 13A, 14A, and 16A are cross-sectional views of configurations of the process sequence along line X-X′ of FIG. 2, and FIGS. 7B, 8B, 13B, 14B, 15B and 16B are cross-sectional views of configurations of the process sequence along line Y-Y′ of FIG. 2.

Referring to FIGS. 7A and 7B, the plurality of fin type active regions FA may be formed in the device region A of the substrate 102 by alternately stacking the plurality of sacrificial semiconductor layers 104 and the plurality of channel layers 106a, 106b, and 106c on the substrate 102 in the device region A one by one, and then etching the plurality of sacrificial semiconductor layers 104, the plurality of channel layers 106a, 106b and 106c, and a part of the substrate 102. Thereafter, the device isolation layer 114 covering sidewalls of the plurality of fin type active regions FA may be formed. An upper surface of the device isolation layer 114 may be lower than an upper surface of each of the plurality of fin type active regions FA.

The plurality of sacrificial semiconductor layers 104 and the plurality of channel layers 106a, 106b, and 106c may include semiconductor materials having different etch selectivity. In some embodiments, the plurality of channel layers 106a, 106b, and 106c may each include a Si layer, and the plurality of sacrificial semiconductor layers 104 may each include a SiGe layer. In some embodiments, the Ge content in the plurality of sacrificial semiconductor layers 104 may be constant. The SiGe layer constituting each of the plurality of sacrificial semiconductor layers 104 may have a constant Ge content selected within the range of about 5 atomic % to about 60 atomic %, for example, about 10 atomic % to about 40 atomic %. The Ge content in the SiGe layer constituting each of the plurality of sacrificial semiconductor layers 104 may be variously selected as necessary.

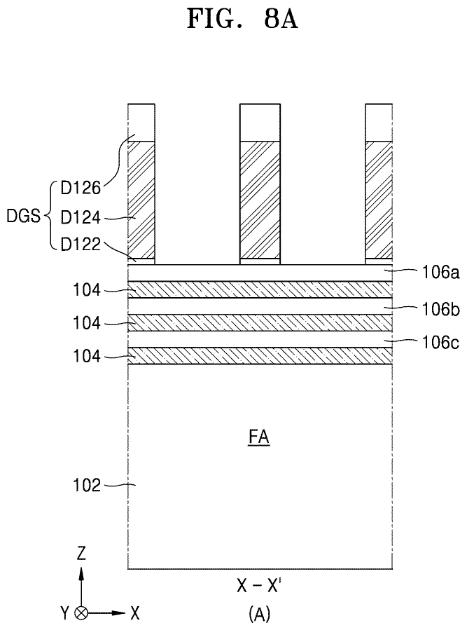

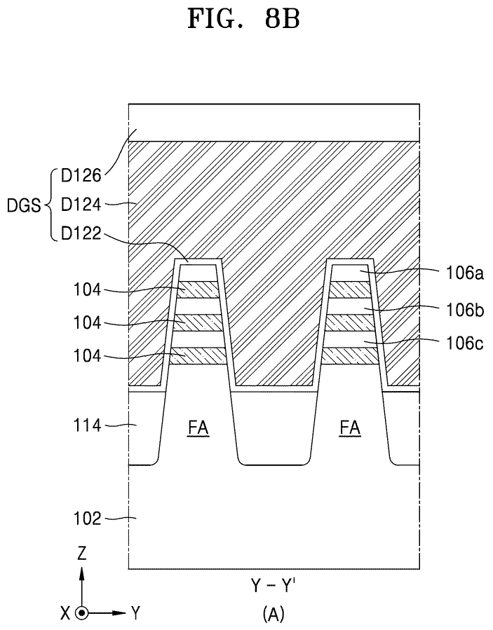

Referring to FIGS. 8A and 8B, a plurality of dummy gate structures DGS may be formed on a stack structure of the plurality of sacrificial semiconductor layers 104 and the plurality of channel layers 106a, 106b, and 106c in the device region A.

Each of the plurality of dummy gate structures DGS may be formed to extend long in the second horizontal direction (Y direction). Each of the plurality of dummy gate structures DGS may have a structure in which an oxide layer D122, a dummy gate layer D124, and a capping layer D126 are sequentially stacked. In some embodiments, the dummy gate layer D124 may include polysilicon, and the capping layer D126 may include a silicon nitride layer.

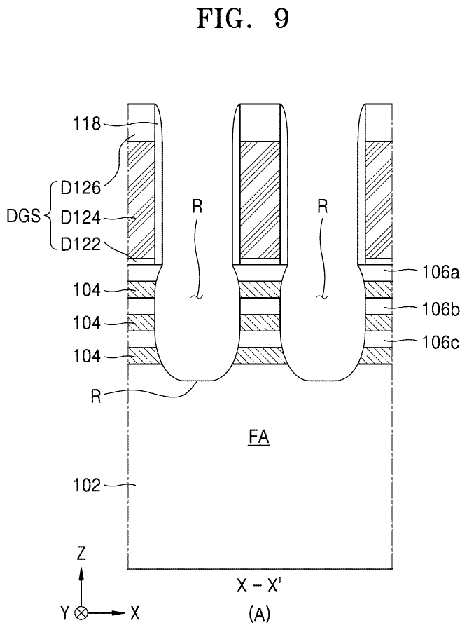

Referring to FIG. 9, the plurality of insulating spacers 118 respectively covering both side walls of the plurality of dummy gate structures DGS in the device region A may be formed, and then a part of the plurality of sacrificial semiconductor layers 104 and each of the plurality of channel layers 106a, 106b and 106c may be removed using the plurality of dummy gate structure DGS and the plurality of insulating spacers 118 as an etching mask, and the exposed fin type active region FA may be etched. As a result, the plurality of recesses R may be formed in the upper portion of the fin type active region FA in the device region A. Dry etching, wet etching, or combination thereof may be used to form the plurality of recesses R.

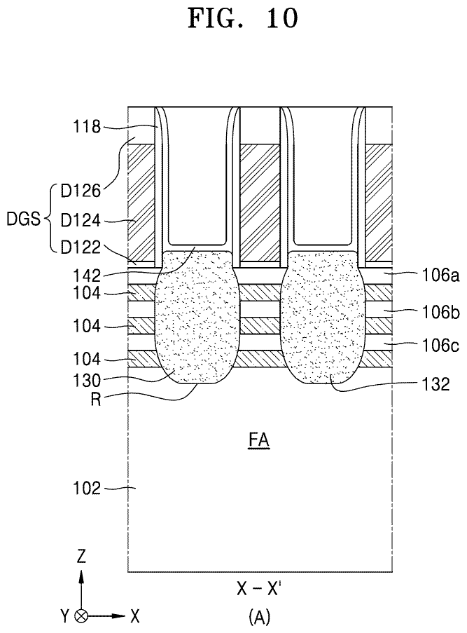

Referring to FIG. 10, the plurality of source regions 130 and drain regions 132 that fill the plurality of recesses R in the device region A may be formed. A selective epitaxial growth process may be performed to form the plurality of source regions 130 and drain regions 132.

In some embodiments, some of the plurality of source regions 130 and drain regions 132 may include a SiGe layer doped with a p-type dopant. A Si source and a Ge source may be used to form the SiGe layer doped with the p-type dopant. As the Si source, silane (SiH₄), disilane (Si₂H₆), trisilane (Si₃H₈), dichlorosilane (SiH₂Cl₂), etc. may be used. As the Ge source, germane (GeH₄), degermaine (Ge₂H₆), trigermane (Ge₃H₈), tetragermane (Ge₄H₁₀), dichlorogermane (Ge₂H₂Cl₂), etc. may be used. The p-type dopant may be selected from B (boron) and Ga (gallium).

In some embodiments, at least some of the plurality of source regions 130 and drain regions 132 may include a Si layer doped with an n-type dopant. At least one of the Si sources above may be used to form the Si layer doped with the n-type dopant. The n-type dopant may be selected from P (phosphorus), As (arsenic), and Sb (antimony).

Thereafter, the insulating liner 142 covering a resultant in which the plurality of source regions 130 and drain regions 132 are formed in the device region A may be formed, the inter-gate insulating layer 144 may be formed on the insulating liner 142, and then, the insulating liner 142 and the inter-gate insulating layer 144 may be planarized to expose an upper surface of the capping layer D126.

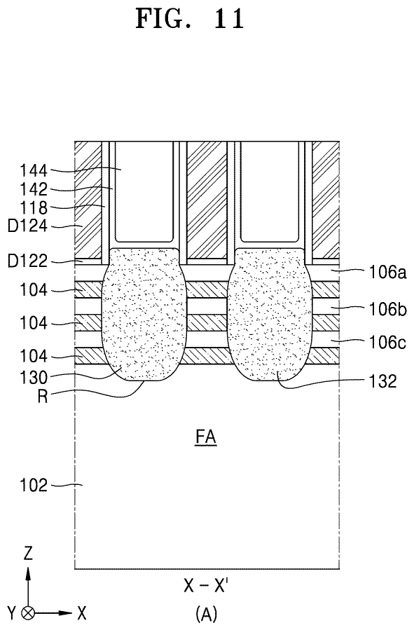

Referring to FIG. 11, the capping layer D126 may be removed from the resultant of FIG. 10 to expose an upper surface of the dummy gate layer D124, and the insulating liner 142 and the inter-gate insulating layer 144 may be partially removed so that the upper surface of the inter-gate insulating layer 144 and the upper surface of the dummy gate layer D124 are approximately at the same level.

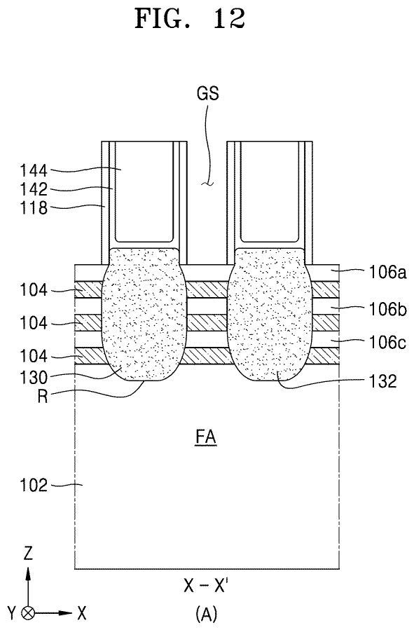

Referring to FIG. 12, the dummy gate layer D124 and the oxide layer D122 there below may be removed from the resultant of FIG. 11. As a result, a gate space GS may be formed in the device region A. The plurality of channel layers 106a, 106b, and 106c may be exposed through the gate space GS.

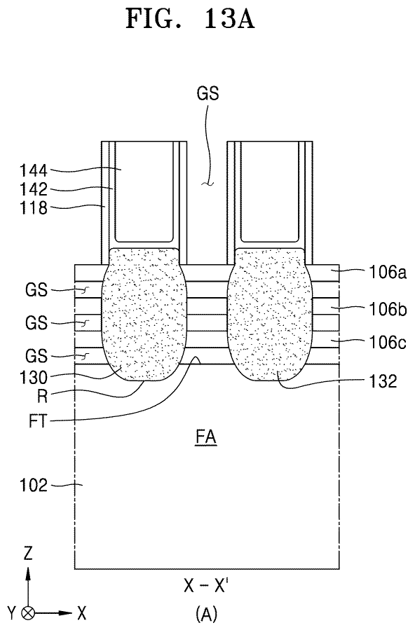

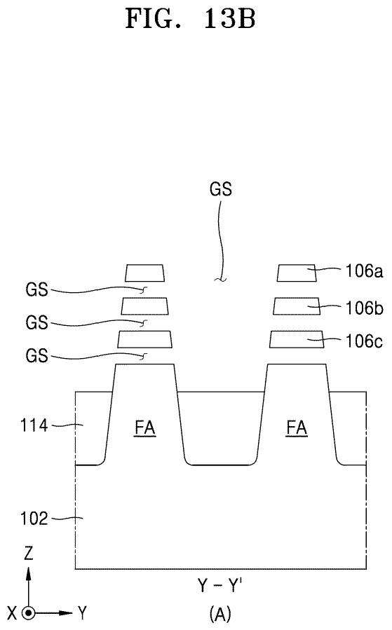

Referring to FIGS. 13A and 13B, the plurality of sacrificial semiconductor layers 104 remaining in the resultant of FIG. 12 in the device region A may be removed through the gate space GS.

As a result, the gate space GS may extend to a space between each of the plurality of channel layers 106a, 106b, and 106c, and a space between the lowermost channel layer 106c and the fin top surface FT of the fin type active region FA in the device region A.

Referring to FIGS. 14A and 14B, a plasma treatment of boron trichloride (BCL₃) may be performed on surfaces of the plurality of channel layers 106a, 106b, and 106c exposed through the gate space GS. The plasma treatment of boron trichloride (BCL₃) may be performed on all surfaces of the plurality of channel layers 106a, 106b, and 106c. A plasma treatment of boron trichloride (BCL₃) proceeding on the space between each of the plurality of channel layers 106a, 106b, and 106c and a plasma treatment of boron trichloride (BCL₃) proceeding on the upper surface of the uppermost channel layer 106a and the lower surface of the lowermost channel layer 106c may be performed at the same pressure and speed. The plasma treatment of boron trichloride (BCL₃) may be performed by remote plasma treatment processing of boron trichloride (BCL₃).

When the plasma treatment processing of boron trichloride (BCL₃) is performed, damage to the plurality of channel layers 106a, 106b, and 106c needs to be minimized. When the hydrogen plasma treatment is performed at a pressure equal to or greater than 100 mtorr, the surfaces of the channel layers 106a, 106b, and 106c may be damaged. For example, ions of boron trichloride (BCL₃) have high kinetic energy at the pressure equal to or greater than 100 mTorr and collide with the surfaces of the plurality of channel layers 106a, 106b, and 106c at a higher speed. Accordingly, the plasma treatment processing of boron trichloride (BCL₃) may be performed in a chamber having a pressure of about 1 mTorr to about 100 mTorr. However, the pressure of the chamber is not limited to these numerical values.

In some embodiments, the plurality of channel layers 106a, 106b, and 106c may include a 2D semiconductor material. The 2D semiconductor material may include at least one of graphene, transition metal dichalcogenides, h-BN, or a combination of two or more thereof. The transition metal dichalcogenides may be a compound of a transition metal and a chalcogen element. For example, the transition metal dichalcogenides may include at least one of MoS₂, WS₂, TaS₂, HfS₂, ReS₂, TiS₂, NbS₂, SnS₂, MOSe₂, WSe₂, TaSe₂, HfSe₂, ReSe₂, TiSe₂, NbSe₂, SnSe₂, MoTe₂, WTe₂, TaTe₂, HfTe₂, ReTe₂, TiTe₂, NbTe₂, or SnTe₂. The h-BN is formed as a hexagonal crystal structure by combining boron (B) and nitrogen (N).

In some embodiments, the plurality of channel layers 106a, 106b, and 106c may be used as the materials described above, but may be doped to further improve the electrical properties of the integrated circuit device 100. The plurality of channel layers 106a, 106b, and 106c may have a doped structure by substituting some of the elements constituting the 2D crystal structure of the plurality of channel layers 106a, 106b, and 106c with other elements or additionally combining other elements with the 2D crystal structure. For example, when the plurality of channel layers 106A, 106B, and 106c are graphene, some of carbon atoms forming graphene are substituted with other atoms, such as boron or nitrogen, or some of the carbon atoms may be combined with other atoms, such as nitrogen.

When the plasma treatment of boron trichloride (BCL₃) is completed, plasma layers BFL may be formed on all surfaces of the plurality of channel layers 106a, 106b, and 106c. The plasma layer BFL may include radicals of BCL₂, BCL, or B. The radicals may have an energetically stable bond in the relationship with the channel layers 106A, 106B, and 106C including graphene, transition metal dichalcogenides, and H-BN. For example, the radicals of BCL₂, BCL, or B may maintain the energetically stable bond in the relationship with MoS₂.

A plasma treatment process performed on the channel layers 106A, 106B, and 106C is not limited to the plasma treatment of boron trichloride (BCL₃). One of plasma treatments of BF₃, BCl₃, BBr₃, and BI₃ may be performed on the exposed surfaces of the plurality of channel layers 106a, 106b, and 106c.

When the plasma treatments of BF₃, BCl₃, BBr₃, and BI₃is completed, the plasma layers BFL may be formed on all surfaces of the plurality of channel layers 106a, 106b, and 106c. The plasma layer BFL may include radicals of BF₂, BF, BCl₂, BCl, BBr₂, BBr, or B. The radicals may have an energetically stable bond in the relationship with the channel layers 106A, 106B, and 106C including graphene, transition metal dichalcogenides, and H-BN. For example, the radicals of BF₂, BF, BCl₂, BCl, BBr₂, BBr, or B may maintain the energetically stable bond in the relationship with MoS₂.

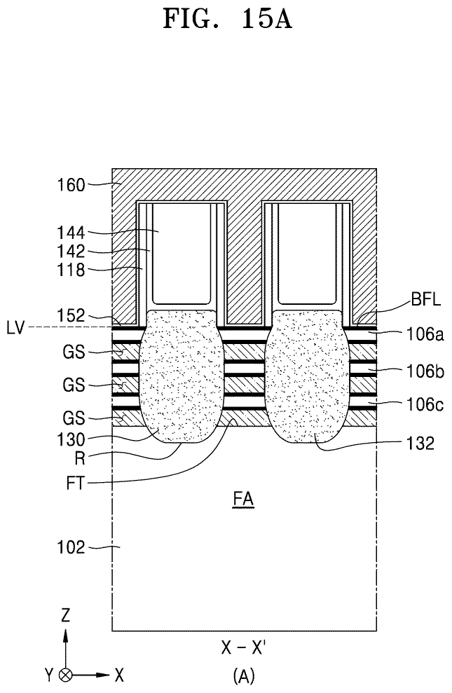

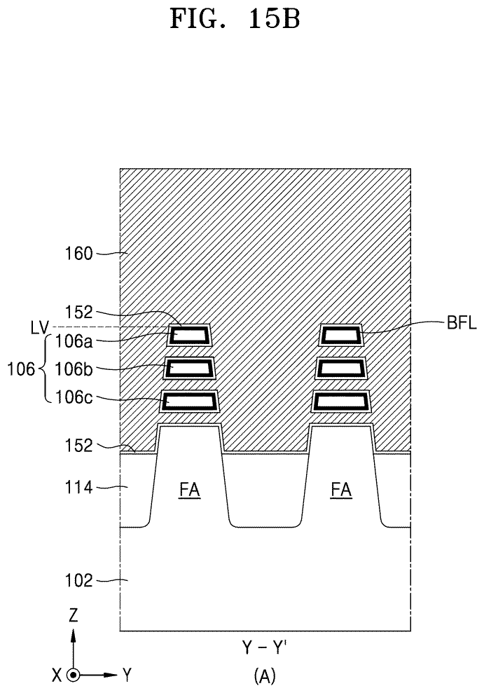

Referring to FIGS. 15A and 15B, a gate dielectric layer 152 conformally covering the exposed surfaces in the device region A may be formed. At this time, the gate dielectric layer 152 may be deposited on the surfaces of the channel layers 106a, 106b, and 106c by ALD. The gate dielectric layer 152 may be formed on all exposed surfaces of the channel layers 106a, 106b, and 106c, forming the plasma layers BFL. The gate dielectric layer 152 may be a single layer or a multiple layer. Also, the gate dielectric layer 152 may include a high-k metal oxide layer. For example, the gate dielectric layer 152 may include at least one of AI₂O₃, HfO₂, ZrO₂, TiN, TaN, Ru, or a combination of two or more thereof. The gate dielectric layer 152 may directly contact the source region 130 and the drain region 132.

Thereafter, the gate layer 160 covering the gate dielectric layer 152 may be formed in the device region A. In the device region A, the gate layer 160 may be formed to cover the upper surface of the inter-gate insulating layer 144 and fill the gate space GS on the gate dielectric layer 152. The gate layer 160 may include at least one of a metal, a metal nitride, a metal carbide, or a combination of two or more thereof. In this regard, the metal may include at least one of Ti, W, Ru, Nb, Mo, Hf, Ni, Co, Pt, Yb, Tb, Dy, Er, or Pd.

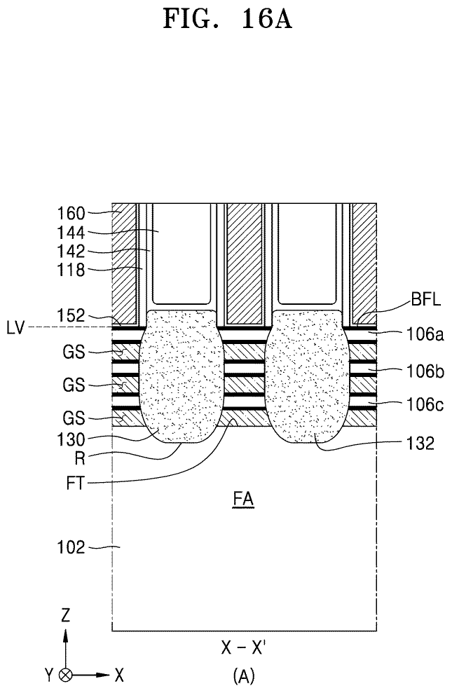

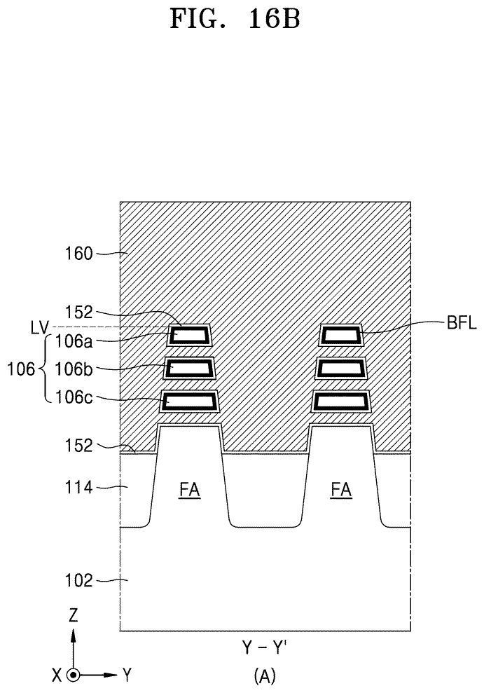

Referring to FIGS. 16A and 16B, a part of each of the gate layer 160 and the gate dielectric layer 152 may be removed from a resultant of FIGS. 15A and 15B so that the upper surface of the inter-gate insulting layer 144 is exposed in the device region A.

As described above, although the method of manufacturing the integrated circuit device 100 illustrated in FIGS. 3 and 4 has been described with reference to FIGS. 7A to 16B, one of ordinary skilled in the art will appreciate that the integrated circuit devices 100, 100A, and 100B illustrated in FIGS. 3 to 6, and integrated circuit devices having various structures modified and changed therefrom may be manufactured, by making various modifications and changes within the scope of the inventive concept.

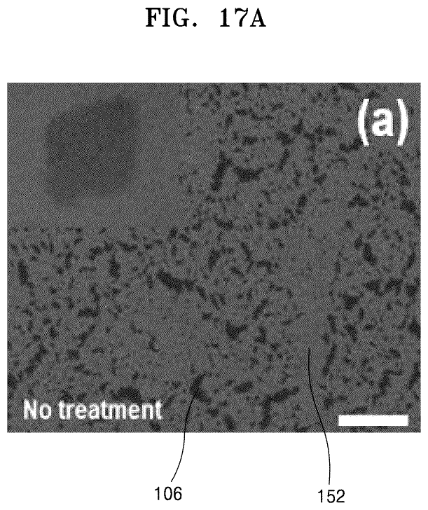

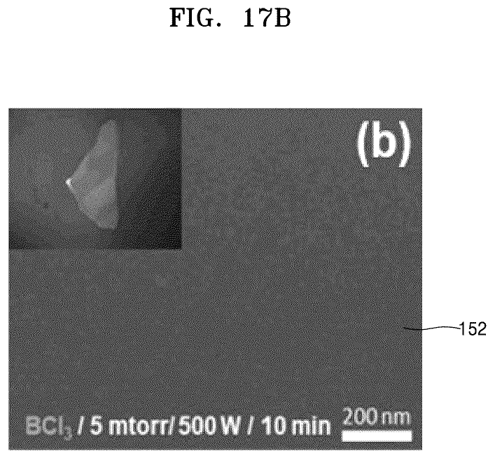

FIGS. 17A and 17B are diagrams comparing surfaces of the channel layers 106a, 106b, and 106c before and after a plasma treatment of BC13. Hereinafter, FIGS. 17A and 17B are described with further reference to FIGS. 3 and 4.

FIG. 17A is a photograph of a surface of the channel layer stack 106 in which the gate dielectric layer 152 is deposited without performing a plasma treatment of boron trichloride (BCL₃) on a surface of the channel layer stack 106. The channel layer stack 106 may be a single layer stack including MoS₂, and the gate dielectric layer 152 may be a single Al₂O₃ layer. The gate dielectric layer 152 may be deposited on the surface of the channel layer stack 106 by ALD. When the plasma treatment of boron trichloride (BCL₃) is not performed on the channel layer stack 106, it may be seen that the gate dielectric layer 152 is not uniformly deposited.

FIG. 17B is a photograph of the surface of the channel layer stack 106 on which the plasma treatment of boron trichloride (BCL₃) is performed and the gate dielectric layer 152 is deposited. Specifically, the plasma treatment of boron trichloride (BCL₃) was performed for 10 minutes at an output of 500 W in a chamber having a pressure of 5 mtorr. The channel layer stack 106 may be a single layer stack including MoS2, and the gate dielectric layer 152 may be a single Al₂O₃ layer. The gate dielectric layer 152 may be deposited on the surface of the channel layer stack 106 by ALD. When the plasma treatment of boron trichloride (BCL₃) is performed on the channel layer stack 106, it may be seen that the gate dielectric layer 152 is uniformly deposited.

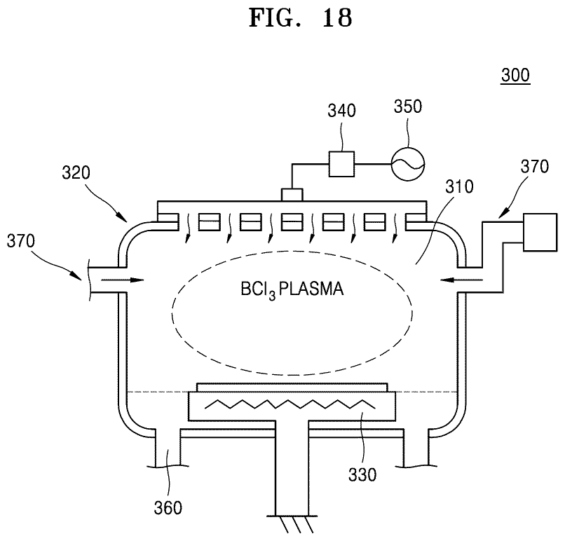

FIG. 18 is a diagram illustrating a plasma apparatus suitable for performing a BCl₃ plasma treatment.

Referring to FIG. 18, a plasma apparatus 300 includes a chamber 320. A chuck 330 supporting a substrate may be provided at a lower portion of the chamber 320. A heater capable of heating the substrate may be provided inside the chuck 330.

An inductively combination type antenna (not shown) may be disposed in the chamber 320. For example, the inductively combination type antenna may be disposed to face the chuck 330. The antenna may be connected to the outside of the chamber 320, and the antenna outside the chamber 320 may be connected to a high frequency power source 350 through a matching box 340. The high frequency power source 350 may be a high frequency power source of about 2 GHz to about 3 GHz. Therefore, a microwave type plasma may be generated by using the plasma apparatus 300.

An exhaust pump 360 may be connected to the lower portion of the chamber 320. In addition, a gas supplier 370 supplying gas into the chamber 320 through the sidewall of the chamber 320 may be provided. The gas supplier 370 may supply a source gas for a plasma treatment. The source gas for the plasma treatment may include boron trichloride (BCL₃), boron trifluoride (BF₃), boron tribromide (BBR₃), and boron triiodide (BI₃).

Hereinafter, a method of forming a gate dielectric layer by performing a plasma treatment on a channel layer using the plasma apparatus 300 is described with further reference to FIGS. 14A and 14B.

First, a substrate to which the channel layer is formed is loaded to the chuck 330 in the chamber 320. The chuck 330 may be heated at a temperature of about 300° C. to about 500° C. The plasma treatment may be performed in the chamber 320 having a pressure of about 1 mTorr to about 100 mTorr. A gas including boron trichloride (BCL₃) may be supplied through the gas supplier 270. Molecules included in the gas are not limited to boron trichloride (BCL₃), but may include boron trifluoride (BF₃), boron tribromide (BBr₃), and boron triiodide (BI₃).

Plasma is generated through the high frequency power source 350 to generate a plasma region 310 of boron trichloride (BCL₃) in the chamber 320. The plasma region 310 of boron trichloride (BCL₃) may be generated adjacent to the chuck 330 on which the substrate is loaded in the chamber 320. The plasma treatment of boron trichloride (BCL₃) may be performed for about 30 seconds to about 20 minutes. The plasma region 310 is not limited to a plasma of boron trichloride (BCL₃), and may include plasma of boron trifluoride (BF3₃), boron tribromide (BBr₃), and boron triiodide (BI₃).

While the inventive concept has been particularly shown and described with reference to embodiments thereof, it will be understood that various changes in form and details may be made therein without departing from the spirit and scope of the following claims.

What is claimed is:

1. A method of manufacturing an integrated circuit device, the method comprising:
alternately stacking sacrificial semiconductor layers and channel layers on a substrate to obtain a stack structure;
forming source regions and drain regions on both sides of the stack structure;
forming a gate space between the channel layers by removing the sacrificial semiconductor layers;
forming the channel layers to be spaced apart from each other in a perpendicular direction to the substrate; and
performing a plasma treatment of boron trichloride (BCL₃) on the channel layers.

2. The method of claim 1, wherein the channel layers include a two-dimensional (2D) semiconductor material.

3. The method of claim 2, wherein the 2D semiconductor material includes at least one of graphene, transition metal dichalcogenides, h-BN, or a combination of two or more thereof.

4. The method of claim 3, wherein the transition metal dichalcogenides include at least one of MoS₂, WS₂, TaS₂, HfS₂, ReS₂, TiS₂, NbS₂, SnS₂, MOSe₂, WSe₂, TaSe₂, HfSe₂, ReSe₂, TiSe₂, NbSe₂, SnSe₂, MoTe₂, WTe₂, TaTe₂, HfTe₂, ReTe₂, TiTe₂, NbTe₂, or SnTe₂.

5. The method of claim 1, wherein the performing of the plasma treatment of boron trichloride (BCL₃) on the channel layers includes forming layers of radicals of BCl₂, BCl, or B on surfaces of the channel layers.

6. The method of claim 1, wherein the performing of the plasma treatment of boron trichloride (BCL₃) on the channel layers is performed by remote plasma treatment processing of boron trichloride (BCL₃).

7. The method of claim 1, wherein the performing of the plasma treatment of boron trichloride (BCL₃) on the channel layers is performed in a chamber having a pressure of about 1 mtorr to about 100 mtorr.

8. The method of claim 1, wherein the performing of the plasma treatment of boron trichloride (BCL₃) on the channel layers is performed on all exposed surfaces of the channel layers.

9. A method of manufacturing an integrated circuit device, the method comprising:
alternately stacking sacrificial semiconductor layers and channel layers on a substrate to obtain a stack structure;
forming source regions and drain regions on both sides of the stack structure;
forming a gate space between the channel layers by removing the sacrificial semiconductor layers;
forming the channel layers to be spaced apart from each other in a perpendicular direction to the substrate;
performing a plasma treatment of boron trichloride (BCL₃) on the channel layers;
forming gate dielectric layers on the channel layers on which the plasma treatment of boron trichloride (BCL₃) is performed; and
forming gate layers covering the gate dielectric layers in the gate space.

10. The method of claim 9, wherein the forming of the gate dielectric layers on the channel layers on which the plasma treatment of boron trichloride (BCL₃) is performed is performed by atomic layer deposition.

11. The method of claim 9, wherein the forming of the gate dielectric layers on the channel layers on which the plasma treatment of boron trichloride (BCL₃) is performed is performed on all exposed surfaces of the channel layers.

12. The method of claim 9, wherein the gate dielectric layers include at least one of AI₂O₃, HfO₂, ZrO₂, TiN, TaN, or a combination of two or more thereof.

13. The method of claim 9, wherein the gate dielectric layers directly contact the source region and the drain region.

14. The method of claim 9, wherein the gate layers include at least one of a metal, a metal nitride, a metal carbide, or a combination of two or more thereof.

15. The method of claim 14, wherein the metal includes at least one of Ti, W, Ru, Nb, Mo, Hf, Ni, Co, Pt, Yb, Tb, Dy, Er, or Pd.

16. A method of manufacturing an integrated circuit device, the method comprising:
alternately stacking sacrificial semiconductor layers and channel layers on a substrate to form a stack structure;
forming source regions and drain regions on both sides of the stack structure;
forming a gate space between the channel layers by removing the sacrificial semiconductor layers;
forming the channel layers to be spaced apart from each other in a perpendicular direction to the substrate;
performing a plasma treatment on the channel layers;
forming gate dielectric layers on the channel layers on which the plasma treatment is performed; and
forming gate layers covering the gate dielectric layers in the gate space,
wherein the plasma treatment is one of plasma treatments of BF₃, BBr₃ or BI₃.

17. The method of claim 16, wherein the performing of the plasma treatment on the channel layers includes forming layers of radicals of BF₂, BF, BBr₂, BBr, BI₂, BI, and B on surfaces of the channel layers.

18. The method of claim 16, wherein the performing of the plasma treatment on the channel layers is performed by remote plasma treatment processing.

19. The method of claim 16, wherein the performing of the plasma treatment on the channel layers is performed in a chamber having a pressure of about 1 mTorr to about 100 mTorr.

20. The method of claim 16, wherein the forming of the gate dielectric layers on the channel layers on which the plasma treatment is performed is performed on all exposed surfaces of the channel layers by atomic layer deposition.
